(19) United States
(12) Patent Application Publication
(10) Pub. No.: US 2002/0055243 A1
(43) Pub. Date: May 9, 2002

(54) Gap-type metallic interconnect and method of manufacture

(75) Inventor: Chiu-Te Lee, Hsinchu (TW)

Correspondence Address: Daniel R. McClure, THOMAS, KAYDEN, HORSTEMEYER & RISLEY, L.L.P., Suite 1750, 100 Galleria Parkway N.W., Atlanta, GA, 30339, US

(73) Assignee: United Microelectronics Corp., Hsinchu (TW)

(21) Appl. No.: 09/736,918

(22) Filed: Dec. 14, 2000

(30) Foreign Application Priority Data
Nov. 6, 2000 (TW) 89123366

(51) Int. Cl. H01L 21/3205

(52) U.S. Cl. 438/586

(57) ABSTRACT

A method of manufacturing a gap-type metallic interconnect. A stack layer is formed over a substrate, wherein the stack layer is formed by stacking dielectric material layers having two different etching rates. A dual damascene opening is formed in the stack layer. A dielectric layer having the same etching rate as one of the dielectric material layers in the stack layer is formed to cover the sidewalls and bottom of the dual damascene opening. A portion of the dielectric layer is removed by an etch back process to expose the substrate at the bottom of the dual damascene opening. A barrier layer is then formed to cover the dielectric layer and the bottom of the dual damascene opening. The dual damascene opening is then filled with a metallic layer for forming a dual damascene structure. Finally, a wet etching is performed to remove the dielectric layer as well as a portion of the stack layer, thereby forming a gap-type dielectric structure. A plasma enhanced chemical vapor deposition is performed to deposit a layer over the substrate for subsequent processing.

### CROSS-REFERENCE TO RELATED APPLICATION

This application claims the priority benefit of Taiwan application serial no. 89123366, filed Nov. 6, 2000.

### BACKGROUND OF THE INVENTION

1. Field of Invention

The present invention relates to a type of metallic interconnect. More particularly, the present invention relates to a gap-type metallic interconnect.

2. Description of Related Art

To match the increase demands for interconnects after the miniaturization of metal-oxide-semiconductor (MOS) transistors, two or more metallic layers has to be incorporated to the design of integrated circuit. In particular, for functionally complicated electronic products such as microprocessors, five or more metallic layers are needed to link up various internal devices.

An inter-metal dielectric layer is used to insulating two neighboring metallic layers in a multi-level interconnect design so that inter-layer short-circuiting is prevented. When width of conductive wires is reduced to 0.13 μm or smaller, back-end shrinkage of wire often leads to serious metal line delay in an integrated circuit. As conductive wires narrows, the presence of parasitic capacitance not only will lead to a time delay, but also will lead to high power consumption resulting in a rise in temperature of the silicon chip. Hence, finding a material capable of replacing the silicon dioxide as an inter-metal dielectric layer is quite urgent. Replacement material for reducing parasitic capacitance includes fluorinated silicate glass (FSG) and low dielectric constant spin-coated polyimide material.

FIGS. 1A through 1C are schematic cross-sectional views showing the progression of steps for manufacturing conventional metallic interconnect.

As shown in FIG. 1A, a substrate having a metal-oxide-semiconductor device and a metallic layer thereon is provided. A dielectric layer 102 is formed over the substrate 100 and then a dual damascene opening 104 is formed in the dielectric layer 102.

As shown in FIG. 1B, a metallic layer 106 that fills the dual damascene opening 104 is formed over the substrate 100.

As shown in FIG. 1C, chemical-mechanical polishing is performed to remove excess metal using the dielectric layer 102 as a polishing stop layer. Ultimately, a metal interconnect 106a is formed.

Although a low dielectric constant material is used to form the inter-metal dielectric layer in the aforementioned method, some defects are present in the structure. For example, the higher the percentage of fluorinated silicate glass, the lower will be the dielectric constant of the dielectric layer. However, too much fluorine atoms in the dielectric layer often leads to some form of instability such as the absorption of moisture to form hydrogen fluoride compound. Moreover, polyimide has high moisture-absorption capacity, poor thermal stability and poor adhesive strength. The greatest problem is that most organic material has low thermal conductivity.

### SUMMARY OF THE INVENTION

Accordingly, one object of the present invention is to provide a method of manufacturing a gap-type metallic interconnect capable of lowering parasitic capacitance and increasing thermal conductivity.

To achieve these and other advantages and in accordance with the purpose of the invention, as embodied and broadly described herein, the invention provides a method of manufacturing a gap-type metallic interconnect. A stack layer is formed over a substrate. The stack layer is formed by stacking dielectric material layers having two different etching rates. A dual damascene opening is formed in the stack layer. A dielectric layer having the same etching rate as one of the dielectric material layers in the stack layer is formed on the sidewalls and bottom of the dual damascene opening. The dielectric layer is etched to expose the substrate at the bottom of the dual damascene opening. A barrier layer is then formed on the stack layer to cover the dielectric layer and the bottom of the dual damascene opening, while a portion of the barrier layer on the stack layer is removed. A metallic layer that fills the dual damascene opening is formed over the substrate. Using the stack layer as a polishing stop layer, chemical-mechanical polishing is performed to remove excess metallic material. Finally, a wet etching is performed to remove the dielectric layer on the sidewalls of the metallic interconnect structure as well as a portion of the stack layer, thereby forming a gap-type dielectric structure. A plasma enhanced chemical vapor deposition is performed to deposit a layer over the substrate for subsequent processing.

One major aspect of this invention is to produce a metallic interconnect having a gap-type structure. The gap-type interconnects uses air to serve as a dielectric medium between an oxide inter-metal dielectric and a metallic wire. Since air has a dielectric constant of almost one, the air effectively lowers the parasitic capacitance between neighboring conductive wires. Ultimately, power consumption is lowered and a higher device performance is obtained.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1C are schematic cross-sectional views showing the progression of steps for manufacturing conventional metallic interconnect;

FIGS. 2A through 2D are schematic cross-sectional views showing the progression of steps for manufacturing a gap-type metallic interconnect according to one preferred embodiment of this invention; and

FIG. 3 is a schematic cross-sectional view of a gap type metallic interconnect structure according to one preferred embodiment of this invention.

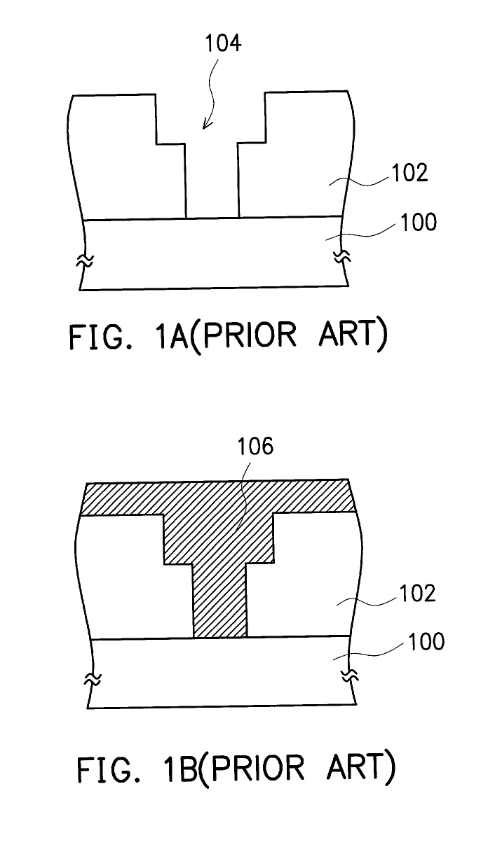

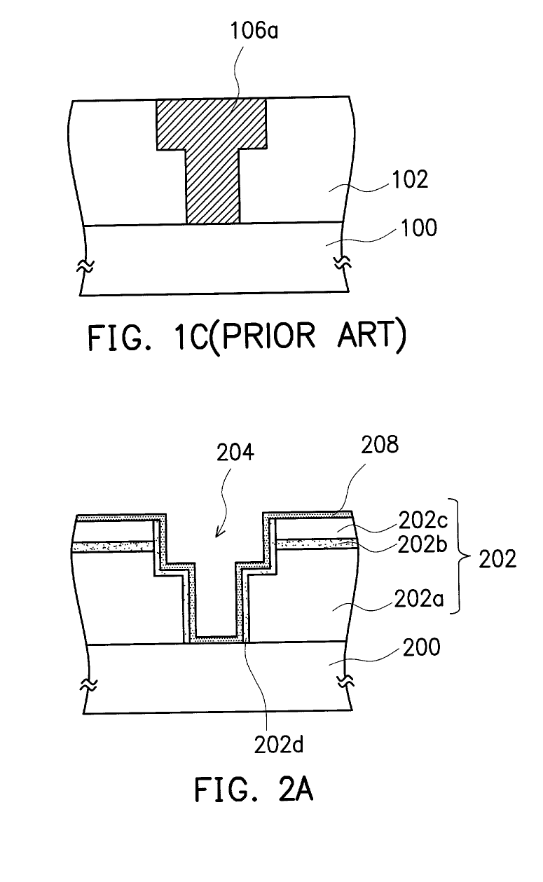

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

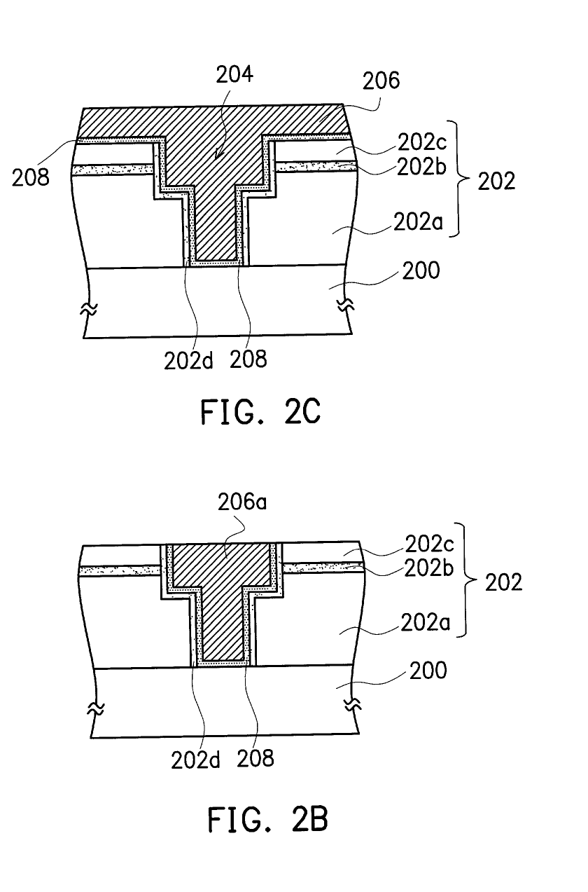

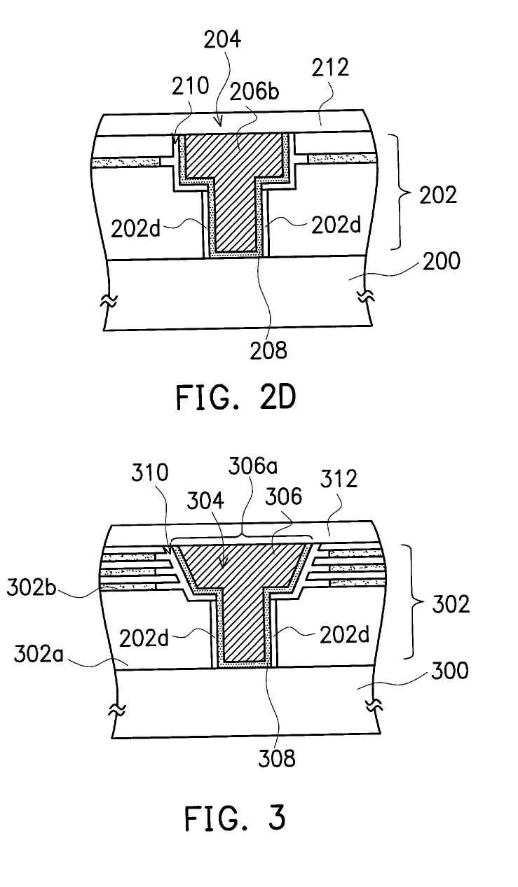

FIGS. 2A through 2D are schematic cross-sectional views showing the progression of steps for manufacturing a gap-type metallic interconnect according to one preferred embodiment of this invention.

As shown in FIG. 2A, a substrate having a metal-oxide-semiconductor device and a metallic layer thereon is provided. A stack layer 202 is formed over the substrate 200. The stack layer 202 is formed by stacking a plurality of dielectric layers having two different etching rates. For example, the stack layer 202 has three dielectric layers 202a, 202b and 202c one over the other. The dielectric layers 202a and 202c are made of materials having the same etching rates while the dielectric layer 202b is made of material having a different etching rate from the dielectric layers 202a and 202c. With this arrangement, etching selectivity can be easily set. Then, a dielectric layer 202d having the same etching rate as the dielectric layer 202b is formed to cover the stack layer 202 and the dual damascene opening 204. The dielectric layer 202b and 202d can include, for example, silicon carbide, silicon nitride, spin-on polymer, spin-on glass, polyimide material or fluorinated silicate glass. The dielectric layer 202d has a thickness of about 100˜300. An etch back process is performed to remove a portion of the dielectric layer 202d at the bottom of the dual damascene opening 204 so that a portion of the substrate 200 is exposed. A barrier layer 208 is further formed to cover the stack layer 202, the dielectric layer 202d, and the exposed portion of the substrate 200.

As shown in FIG. 2B, a portion of the barrier layer 208 on the stack layer 202 is removed performed A metallic layer 206 is formed over the substrate 200 to fill the dual damascene opening 204. The metallic layer 206 can be a copper layer formed, for example, by chemical vapor deposition.

As shown in FIG. 2C, chemical-mechanical polishing is performed using the stack layer 202 as a polishing stop layer to remove excess metal, thereby forming a dual damascene structure 206a that serves as a metallic interconnect.

Finally, as shown in FIG. 2D, a wet etching operation is performed to remove the dielectric layer 202d adjacent to the metallic interconnect 206a within the dual damascene opening 204 as well as a portion of the stack layer 202. Ultimately, a hollow structure 210 is formed. Plasma chemical vapor deposition is next carried out to form a layer 212 over the substrate 200. Since material deposited in a plasma chemical vapor deposition process will not fill the interior of the hollow structure 210, a gap-type metallic interconnect 206b is formed.

FIG. 3 is a schematic cross-sectional view of a gap type metallic interconnect structure according to one preferred embodiment of this invention. As shown in FIG. 3, the structure includes a stack layer 302 having a dual damascene opening 304 therein above a substrate 300. There is a gap type metallic interconnect 306a inside the dual damascene opening 304. A hollow structure 310 exists between the dual damascene opening 304 and the gap-type metallic interconnect 306a. The metallic interconnect 306a is formed from a metal layer 306 and an adjacent barrier layer 308. On the surface of the stack layer 302 and the metallic interconnect 306a, there is a deposited layer 312. The stack layer 302 is made from two different types of dielectric material layers 302a and 302b stacked alternately over each other, while the alternating dielectric layers in the stack layer 302 can be increased to increase a volume of the hollow structure 310.

In this invention, air serves as a dielectric medium between an oxide inter-metal dielectric and a metallic wire. Since air has a dielectric constant of almost one, the air effectively lowers the parasitic capacitance between neighboring conductive wires and increases thermal conduction. Ultimately, power consumption is lowered and a higher device performance is obtained.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing a gap-type metallic interconnect, comprising the steps of:
providing a substrate;
forming a stack layer over the substrate;
forming a dual damascene opening in the stack layer;
forming a first dielectric layer over the stack layer and the interior surface of the dual damascene opening and then etching back the dielectric layer to expose the substrate at the bottom of the dual damascene opening;
forming a barrier layer for covering the first dielectric layer and the exposed substrate, wherein the barrier layer is adjacent to the first dielectric layer;
removing a part of the barrier layer on the stack layer;
forming a metallic layer over the substrate for filling the dual damascene opening;
removing a portion of the metallic layer on the stack layer, with the stack layer serving as a polishing stop layer, so as to form a metallic interconnect;
removing the first dielectric layer adjacent to the metallic interconnect within the dual damascene opening and a portion of the stack layer to form a hollow structure; and
forming a deposition layer on the substrate to form the gap type metallic interconnect.

2. The method of claim 1, wherein the stack layer is composed of two different types of dielectric material layers stacking alternately over each other.

3. The method of claim 2, wherein a volume of the hollow structure is increased by increasing number of the dielectric layers alternatively stacked in the stack layer.

4. The method of claim 2, wherein the dielectric layers in the stack layer includes a second dielectric layer, a third dielectric layer and a fourth dielectric layer.

5. The method of claim 4, wherein the second and the fourth dielectric layer are made of dielectric materials having the same etching rates while the third dielectric layer has a different etching rate from the second and fourth dielectric layers.

6. The method of claim 4, wherein the material constituting the third dielectric layer is selected from a group consisting of silicon carbide, silicon nitride, spin-on polymer, spin-on glass, polyimide material and fluorinated silicate glass.

7. The method of claim 4, wherein the first dielectric layer and the third dielectric layer are made of the dielectric materials having the same etching rates.

8. The method of claim 7, wherein the material constituting the first dielectric layer is selected from a group consisting of silicon carbide, silicon nitride, spin-on polymer, spin-on glass, polyimide material and fluorinated silicate glass.

9. The method of claim 1, wherein material forming the metallic layer includes copper.

10. The method of claim 1, wherein the step of removing the dielectric layer on the sidewalls of the metallic interconnect and the portion of the stack layer includes wet etching.

11. The method of claim 1, wherein the step of forming the deposition layer includes plasma enhanced chemical vapor deposition.

12. A gap-type metallic interconnect structure, comprising:
a stack layer; and
a metallic interconnect, wherein the metallic interconnect is embedded within the stack layer, and there is a hollow structure between a portion of the metallic interconnect and the stack layer.

13. The structure of claim 12, wherein the stack layer is composed of two different types of dielectric material layers stacking alternately over each other.

14. The structure of claim 13, wherein the dielectric layers in the stack layer at least includes a first, a second and a third dielectric layer, the first and the third dielectric layer are formed from an identical dielectric material while the second dielectric layer is formed from a different dielectric material.

15. The structure of claim 14, wherein material constituting the second dielectric layer is selected from a group consisting of silicon carbide, silicon nitride, spin-on polymer, spin-on glass, polyimide material and fluorinated silicate glass.

16. The structure of claim 12, wherein a volume of the hollow structure is increased by increasing number of the dielectric layers alternatively stacked in the stack layer.

17. The structure of claim 12, wherein the metallic interconnect includes a metallic layer and a barrier layer.

18. The structure of claim 17, wherein material constituting the metallic layer includes copper.

19. The structure of claim 12, wherein the gap type metallic interconnect structure further includes a deposition layer on the stack layer and the metallic interconnect.
